(19) United States
(12) Patent Application Publication
(10) Pub. No.: US 2025/0280584 A1
(43) Pub. Date: Sep. 4, 2025

(54) SEMICONDUCTOR MEMORY DEVICE MANUFACTURING METHOD

(71) Applicant: NANYA TECHNOLOGY CORPORATION, New Taipei city (TW)

(72) Inventor: Hsu CHIANG, New Taipei City (TW)

(21) Appl. No.: 18/593,865

(22) Filed: Mar. 2, 2024

(51) Int. Cl. H01L 21/28; H01L 29/66

(52) U.S. Cl. CPC H10D 64/035; H10D 30/0411

(57) ABSTRACT

A semiconductor memory device manufacturing method includes the following steps. A gate structure is formed on a substrate. First gate nitride spacers are formed around the gate structure. A gate oxide material is formed between adjacent first gate nitride spacers. A first gate cap nitride layer is formed. The first gate cap nitride layer is patterned and used as a hard mask to etch gate contact trenches. Second gate nitride spacers are formed in the gate contact trenches. A gate contact oxide material is formed in the gate contact trenches. A second gate cap nitride layer is formed. The second gate cap nitride layer is patterned to form an opening to expose the gate contact oxide material. The gate contact oxide material is removed from the gate contact trenches. A gate contact metal material is formed into the gate contact trenches.

### BACKGROUND

### Field of Disclosure

The present disclosure relates to a semiconductor memory device manufacturing method.

### Description of Related Art

An integrated circuit (IC) device (also referred to as a semiconductor chip) can contain millions of transistors and other circuit elements that are fabricated on a single silicon crystal substrate (wafer). In a semiconductor memory device, a gate structure is a crucial component responsible for controlling the flow of electrical current between the source and drain terminals of the transistor. For example, in a NAND flash memory cell, the gate structure plays a crucial role in storing and retrieving data. By applying specific voltages to the gate, electrons can be trapped or released in the floating gate, altering the cell's electrical characteristics and storing binary data. This manipulation of charge within the gate structure enables the memory device to retain information even when power is removed.

### SUMMARY

The present disclosure provides semiconductor memory devices and manufacturing methods thereof to deal with the needs of the prior art problems.

In one or more embodiments, a semiconductor memory device manufacturing method including: forming a gate structure on a substrate, wherein the gate structure comprises a gate conductive portion and a gate oxide layer; forming first gate nitride spacers around the gate structure; forming a gate oxide material between adjacent ones of the first gate nitride spacers; forming a first gate cap nitride layer over the gate structure, the first gate nitride spacers and the gate oxide material; patterning the first gate cap nitride layer and using the patterned first gate cap nitride layer as a hard mask to etch gate contact trenches in the gate oxide material, wherein each gate contact trench exposes a corresponding gate source/drain region in the substrate; forming second gate nitride spacers in the gate contact trenches; forming a gate contact oxide material in the gate contact trenches and over the second gate nitride spacers; forming a second gate cap nitride layer over the gate structure, the first and second gate nitride spacers and the gate contact oxide material; patterning the second gate cap nitride layer to form an opening to expose the gate contact oxide material; removing the gate contact oxide material from the gate contact trenches; and forming a gate contact metal material into the gate contact trenches.

In one or more embodiments, the gate conductive portion includes a polysilicon portion and a tungsten portion on a top of the polysilicon portion.

In one or more embodiments, the gate contact metal material is tungsten.

In one or more embodiments, the method further includes: performing a chemical mechanical polishing process to remove excess gate oxide material.

In one or more embodiments, the method further includes: performing a chemical mechanical polishing process to remove excess gate contact oxide material.

In one or more embodiments, the method further includes: performing a chemical mechanical polishing process to remove excess gate contact metal material.

In one or more embodiments, an inner sidewall of each gate contact trench is perpendicular to the corresponding gate source/drain region.

In one or more embodiments, the method further includes: performing a source/drain implant process to the corresponding gate source/drain region.

In one or more embodiments, the second gate nitride spacers are formed by an atomic layer deposition process.

In one or more embodiments, a semiconductor memory device manufacturing method including: forming a gate structure on a substrate; forming first gate nitride spacers around the gate structure; forming a gate oxide material between adjacent ones of the first gate nitride spacers; forming a first gate cap nitride layer over the gate structure, the first gate nitride spacers and the gate oxide material; patterning the first gate cap nitride layer and using the patterned first gate cap nitride layer as a hard mask to etch gate contact trenches in the gate oxide material, wherein each gate contact trench has a first opening having a first width; forming second gate nitride spacers in the gate contact trenches; forming a gate contact oxide material in the gate contact trenches and over the second gate nitride spacers; forming a second gate cap nitride layer over the gate structure, the first and second gate nitride spacers and the gate contact oxide material; patterning the second gate cap nitride layer to form a second opening to expose the gate contact oxide material, wherein the second opening has a second with greater than the first width; removing the gate contact oxide material from the gate contact trenches; and forming a gate contact metal material into the gate contact trenches to form a gate contact.

In one or more embodiments, the gate structure includes a gate conductive portion and a gate oxide layer, the gate conductive portion includes a polysilicon portion and a tungsten portion on a top of the polysilicon portion.

In one or more embodiments, the gate contact metal material is tungsten.

In one or more embodiments, the method further includes: performing a chemical mechanical polishing process to remove excess gate oxide material.

In one or more embodiments, the method further includes: performing a chemical mechanical polishing process to remove excess gate contact oxide material.

In one or more embodiments, the method further includes: performing a chemical mechanical polishing process to remove excess gate contact metal material.

In one or more embodiments, each gate contact includes a T-shaped profile.

In one or more embodiments, the second gate nitride spacers are formed by an atomic layer deposition process.

In one or more embodiments, each gate contact trench exposes a corresponding gate source/drain region in the substrate.

In one or more embodiments, the method further includes: performing a source/drain implant process to the corresponding gate source/drain region.

In one or more embodiments, each second gate nitride spacer has a uniform thickness and extends in a lengthwise direction perpendicular to the corresponding gate source/drain region.

In sum, the semiconductor memory device manufacturing method disclosed herein utilizes the process steps to form vertical gate oxide spacers, thereby forming a uniform distance between the gate structure and the gate contact, and the gate contact is equipped with a wider bottom in contact with the gate source/drain region.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIGS. 1-5 illustrate cross-sectional views of several steps of a semiconductor memory manufacturing process according to some embodiments of the present disclosure; and

FIG. 6 illustrates a flowchart of several steps of a semiconductor memory manufacturing process according to some embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

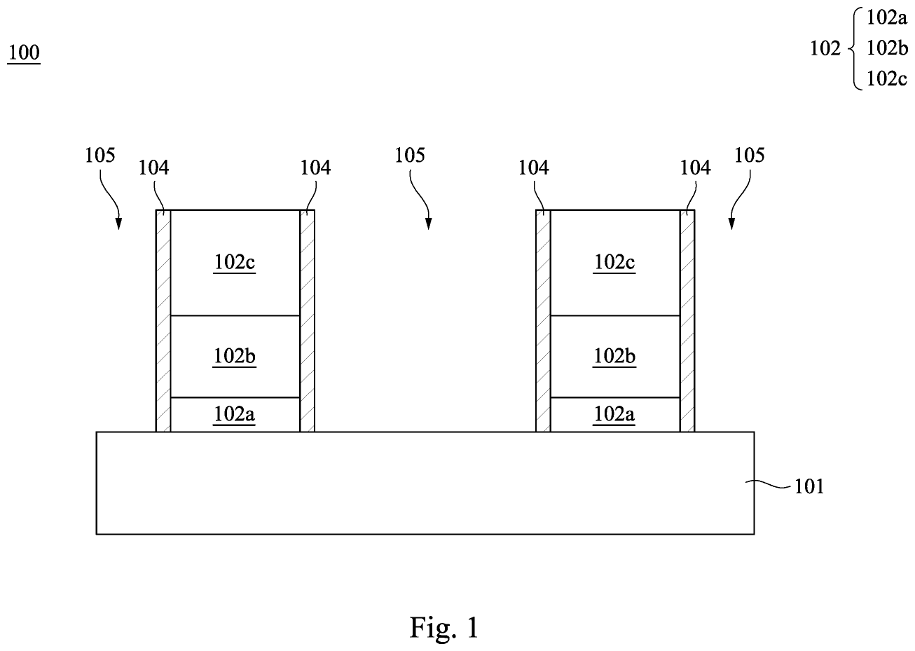

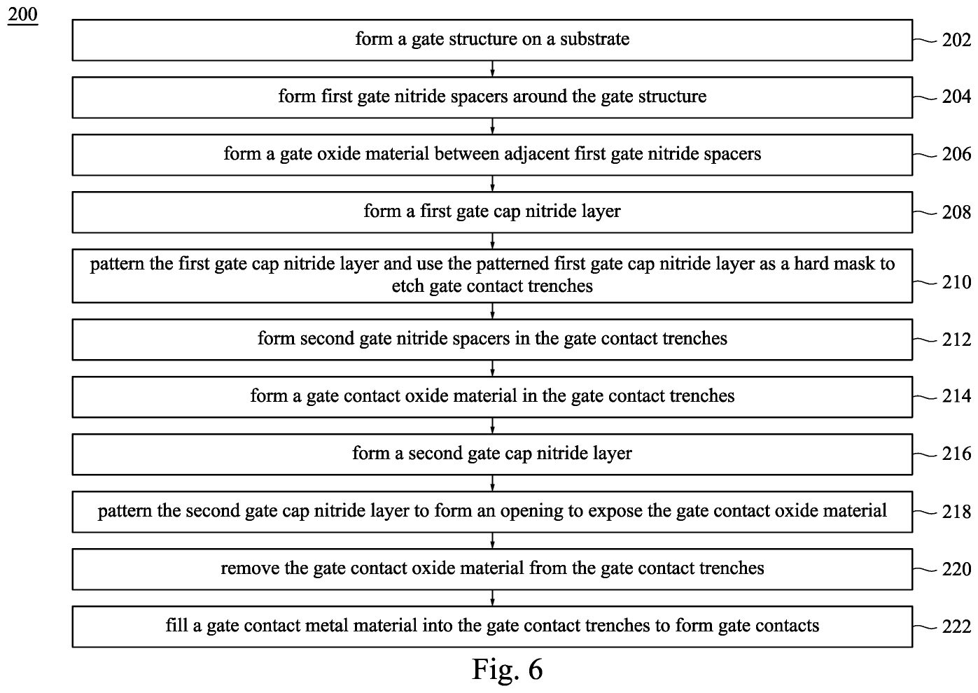

Reference is made to FIGS. 1-6, FIGS. 1-5 illustrate cross-sectional views of several steps of a semiconductor memory manufacturing process according to some embodiments of the present disclosure, and FIG. 6 illustrates a flowchart of several steps of a semiconductor memory manufacturing process 200 according to some embodiments of the present disclosure. The cross-sectional view illustrates a portion of a memory device 100 including gate structures 102. A semiconductor substrate 101 is processed to form active areas. Several steps are typically involved in semiconductor processing. A suitable semiconductor substrate, such as silicon (Si), is chosen based on the desired device specifications and requirements. A thin layer of silicon dioxide (SiO₂) may be on the surface of the substrate. This can be achieved through thermal oxidation, where the substrate is exposed to an oxygen-rich environment at high temperatures, or by using deposition techniques such as chemical vapor deposition (CVD) or plasma-enhanced chemical vapor deposition (PECVD). A layer of photosensitive material, known as photoresist, is coated onto the oxide layer. Then, expose the photoresist to ultraviolet (UV) light through a photomask containing the desired pattern. This step transfers the pattern onto the photoresist. The exposed photoresist is developed using a suitable developer solution. This selectively removes either the exposed (positive photoresist) or unexposed (negative photoresist) regions of the photoresist, leaving behind the desired pattern. An etching process, such as plasma etching or wet etching, is used to selectively remove the exposed oxide layer where the active area will be formed. The patterned photoresist acts as a mask, protecting the regions where the oxide is desired. Ion implantation is performed to introduce p-type or n-type dopant atoms into the exposed semiconductor substrate regions where the active devices will be formed. The dopants modify the electrical properties of the substrate, creating regions with desired conductivity characteristics. The implanted dopants are activated and crystal lattice damage caused by the implantation process is repaired through an annealing process. This step typically involves subjecting the substrate to high temperatures for a specific duration.

In step 202 of the process 200 (referring to FIG. 1), a gate structure 102 can be formed on a substrate 101. In one or more embodiments, to form gate structures 102 on a substrate 101 may include following steps. A clean substrate 101, typically made of silicon, can be prepared. A thin gate oxide layer 102a may be applied on the substrate 101 to act as an insulating layer. A layer of polysilicon portion 102b can be deposited on top of the gate oxide layer 102a. This layer serves as the foundation for the gate conductive portion. A layer of tungsten portion 102c can be deposited on the polysilicon portion 102b. This is usually done through a process like chemical vapor deposition (CVD). Photolithography techniques are utilized to selectively expose and develop the polysilicon and tungsten layers, forming the desired gate structure pattern. The exposed areas of the polysilicon and tungsten layers are etched away, thereby leaving behind the gate structures according to the pattern. A thorough cleaning step may be performed to remove any residues and contaminants from the substrate surface. An annealing process may be optionally performed to improve the structural integrity and electrical properties of the gate structures 102.

In step 204 of the process 200 (referring to FIG. 1), first gate nitride spacers 104 can be formed around the gate structure 102. In one or more embodiments, a layer of nitride material can be deposited on the entire substrate 101, covering the gate structures 102 and the surrounding area. An anisotropic etching process, such as reactive ion etching (RIE), may be utilized to selectively remove the nitride material from the horizontal surfaces, leaving the nitride material only on the vertical or lateral sidewalls of the gate structure 102.

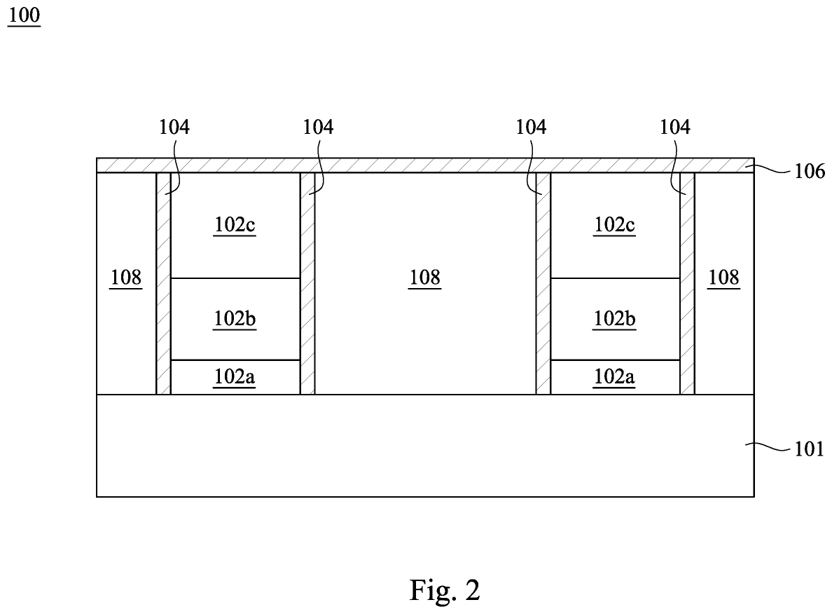

In step 206 of the process 200 (referring to FIG. 2), a gate oxide material 108 can be formed in void spaces 105 between adjacent first gate nitride spacers 104. In one or more embodiments, the gate oxide material 108 can be fully filled into the void spaces 105 between adjacent first gate nitride spacers 104. The gate oxide material 108 can be filled through techniques like chemical vapor deposition (CVD). A chemical mechanical polishing process may be performed to remove excess gate oxide material 108 and create a smooth and even surface.

In step 208 of the process 200 (referring to FIG. 2), a first gate cap nitride layer 106 can be formed over the gate structure 102, the first gate nitride spacers 104 and the gate oxide material 108. In one or more embodiments, a layer of nitride material can be deposited over the entire substrate, covering the gate structure 102, first gate nitride spacers 104, and gate oxide material 108. This can be done using techniques like chemical vapor deposition (CVD) or physical vapor deposition (PVD).

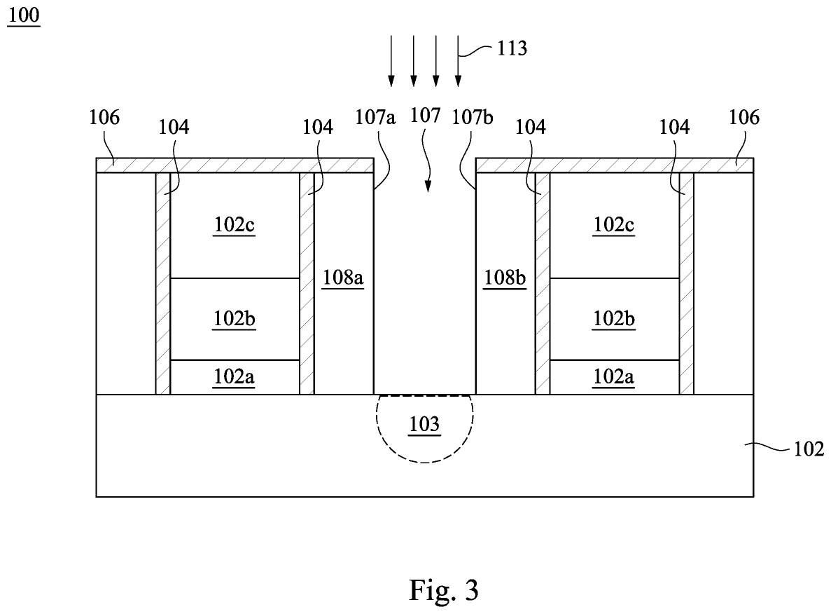

In step 210 of the process 200 (referring to FIG. 3), the first gate cap nitride layer 106 can be patterned and used as a hard mask to etch gate contact trenches 107 in the gate oxide material 108. In one or more embodiments, a photoresist layer may be applied on top of the first gate cap nitride layer 106, and the photoresist layer is exposed to UV light through a photomask containing a desired pattern for gate contact trenches 107. The photoresist layer is then developed to create openings corresponding to the desired trench pattern. An anisotropic etching process (e.g., reactive ion etching or plasma etching) can be utilized to selectively remove the exposed areas of the first gate cap nitride layer 106. This leaves behind the patterned first gate cap nitride layer 106 as a hard mask. An etching process is performed using the patterned first gate cap nitride layer 106 as a hard mask to etch gate contact trenches 107 into the gate oxide material 108 until each gate contact trench 107 exposes a corresponding gate source/drain region 103 in the substrate 101.

In one or more embodiments, an inner sidewall (107a, 107b) of each gate contact trench 107 is perpendicular to a top surface of the corresponding gate source/drain region 103. In one or more embodiments, a source/drain implant process 113 can be performed to the corresponding gate source/drain region 103 to alter doping concentrations in the source and drain areas adjacent to the gate structure. With vertical sidewall (107a, 107b) of each gate contact trench 107, the gate source/drain region 103 can be defined with a broad area.

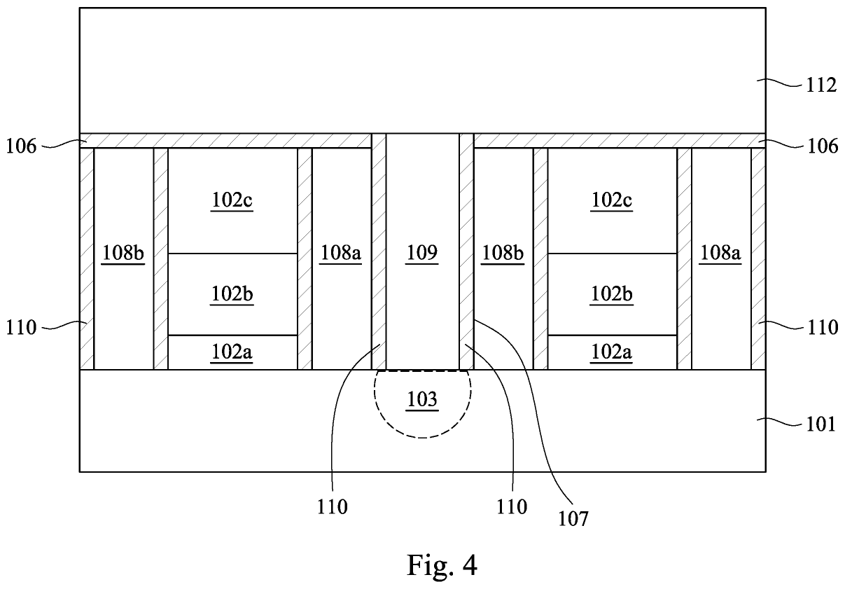

In step 212 of the process 200 (referring to FIG. 4), second gate nitride spacers 110 can be formed in the gate contact trenches 107 to be in contact with lateral sidewalls (107a, 107b) of the remaining gate oxide material (108a, 108b) that is not etched away. In one or more embodiments, the second gate nitride spacers 110 can be deposited using an atomic layer deposition process to provide a conformal coating, ensuring uniform coverage on the lateral sidewalls (107a, 107b) of the remaining gate oxide material (108a, 108b) in the gate contact trenches 107. An etch-back process may be optionally performed to remove excess material from the top surface, leaving the nitride spacers primarily on the sidewalls. In one or more embodiments, each second gate nitride spacer 110 has a uniform thickness and extends in a lengthwise direction perpendicular to the corresponding gate source/drain region 103.

In step 214 of the process 200 (referring to FIG. 4), a gate contact oxide material 109 can be formed in the gate contact trenches 107 and over the second gate nitride spacers 110. In one or more embodiments, a deposition technique like Chemical Vapor Deposition (CVD) or Atomic Layer Deposition (ALD) can be utilized to deposit the gate contact oxide material 109. A CMP process may be performed to planarize the surface, removing excess oxide material and ensuring a smooth, even surface.

In step 216 of the process 200 (referring to FIG. 4), a second gate cap nitride layer 112 can be formed over the gate structure 102, the first and second gate nitride spacers (104, 110), the first gate cap nitride layer 106 and the gate contact oxide material 109. In one or more embodiments, a layer of nitride material can be deposited over the entire substrate, covering the gate structure 102, the first and second gate nitride spacers (104, 110), the remaining gate oxide material (108a, 108b) and the gate contact oxide material 109. This can be done using techniques like chemical vapor deposition (CVD) or physical vapor deposition (PVD).

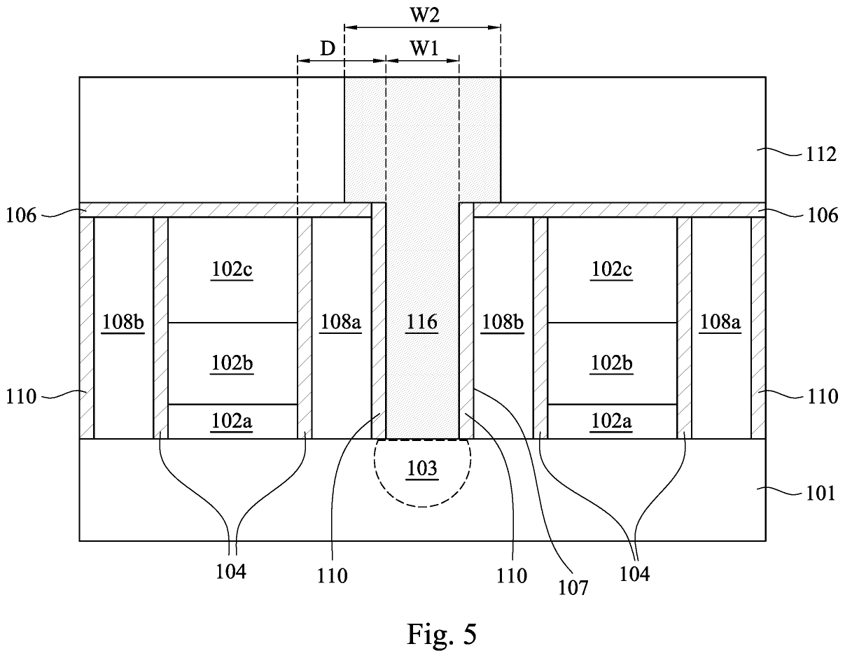

In step 218 of the process 200 (referring to FIG. 5), the second gate cap nitride layer 112 can be patterned to form an opening 115 to expose the gate contact oxide material 109. In one or more embodiments, a photoresist layer may be applied on top of the second gate cap nitride layer 112, and the photoresist layer is exposed to UV light through a photomask containing a desired pattern for the opening 115. The photoresist layer is then developed to create openings corresponding to the desired trench pattern. An anisotropic etching process (e.g., reactive ion etching or plasma etching) can be utilized to selectively remove the exposed areas of the second gate cap nitride layer 112 until the gate contact oxide material 109 is exposed. In one or more embodiments, the opening 115 has a width W2 greater than a width W1 of the gate contact trench 107. After step 218, a gate spacer stack, including the second gate nitride spacer 110, the remaining gate oxide material (108a or 108b) and the first gate nitride spacer 104, is formed on sidewalls of the gate structure 102 with a uniform thickness (e.g., a uniform distance D).

In step 220 of the process 200 (referring to FIG. 5), the gate contact oxide material 109 can be removed from the gate contact trenches 107. In one or more embodiments, a wet etching can be used to remove the gate contact oxide material 109 from the gate contact trenches 107.

In step 222 of the process 200 (referring to FIG. 5), a gate contact metal material can be filled into the gate contact trench 107 and the opening 115 to form a gate contact 116. In one or more embodiments, each gate contact 116 comprises a T-shaped profile. In one or more embodiments, the gate contact metal material is tungsten or tungsten-based material. Since the gate spacer stack has a uniform thickness, a distance D between the gate structure 102 and the gate contact 116 is maintained substantially the same from the tungsten portion 102c to the gate oxide layer 102a, and the gate contact 116 has a wider bottom in contact with the gate source/drain region 103.

In sum, the semiconductor memory device manufacturing method disclosed herein utilizes the process steps to form vertical gate oxide spacers, thereby forming a uniform distance between the gate structure and the gate contact, and the gate contact is equipped with a wider bottom in contact with the gate source/drain region.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A semiconductor memory device manufacturing method comprising:
forming a gate structure on a substrate, wherein the gate structure comprises a gate conductive portion and a gate oxide layer;
forming first gate nitride spacers around the gate structure;
forming a gate oxide material between adjacent ones of the first gate nitride spacers;
forming a first gate cap nitride layer over the gate structure, the first gate nitride spacers and the gate oxide material;
patterning the first gate cap nitride layer and using the patterned first gate cap nitride layer as a hard mask to etch gate contact trenches in the gate oxide material, wherein each gate contact trench exposes a corresponding gate source/drain region in the substrate;
forming second gate nitride spacers in the gate contact trenches;
forming a gate contact oxide material in the gate contact trenches and over the second gate nitride spacers;
forming a second gate cap nitride layer over the gate structure, the first and second gate nitride spacers and the gate contact oxide material;
patterning the second gate cap nitride layer to form an opening to expose the gate contact oxide material;
removing the gate contact oxide material from the gate contact trenches; and
forming a gate contact metal material into the gate contact trenches.

2. The method of claim 1, wherein the gate conductive portion comprises a polysilicon portion and a tungsten portion on a top of the polysilicon portion.

3. The method of claim 1, wherein the gate contact metal material comprises tungsten.

4. The method of claim 1 further comprising: performing a chemical mechanical polishing process to remove excess gate oxide material.

5. The method of claim 1 further comprising: performing a chemical mechanical polishing process to remove excess gate contact oxide material.

6. The method of claim 1 further comprising: performing a chemical mechanical polishing process to remove excess gate contact metal material.

7. The method of claim 1, wherein an inner sidewall of each gate contact trench is perpendicular to the corresponding gate source/drain region.

8. The method of claim 1 further comprising: performing a source/drain implant process to the corresponding gate source/drain region.

9. The method of claim 1, wherein the second gate nitride spacers are formed by an atomic layer deposition process.

10. A semiconductor memory device manufacturing method comprising:
forming a gate structure on a substrate;
forming first gate nitride spacers around the gate structure;
forming a gate oxide material between adjacent ones of the first gate nitride spacers;
forming a first gate cap nitride layer over the gate structure, the first gate nitride spacers and the gate oxide material;
patterning the first gate cap nitride layer and using the patterned first gate cap nitride layer as a hard mask to etch gate contact trenches in the gate oxide material, wherein each gate contact trench has a first opening having a first width;
forming second gate nitride spacers in the gate contact trenches;
forming a gate contact oxide material in the gate contact trenches and over the second gate nitride spacers;
forming a second gate cap nitride layer over the gate structure, the first and second gate nitride spacers and the gate contact oxide material;
patterning the second gate cap nitride layer to form a second opening to expose the gate contact oxide material, wherein the second opening has a second with greater than the first width;
removing the gate contact oxide material from the gate contact trenches; and
forming a gate contact metal material into the gate contact trenches to form gate contacts.

11. The method of claim 10, wherein the gate structure comprises a gate conductive portion and a gate oxide layer, the gate conductive portion comprises a polysilicon portion and a tungsten portion on a top of the polysilicon portion.

12. The method of claim 10, wherein the gate contact metal material comprises tungsten.

13. The method of claim 10 further comprising: performing a chemical mechanical polishing process to remove excess gate oxide material.

14. The method of claim 10 further comprising: performing a chemical mechanical polishing process to remove excess gate contact oxide material.

15. The method of claim 10 further comprising: performing a chemical mechanical polishing process to remove excess gate contact metal material.

16. The method of claim 10, wherein each gate contact comprises a T-shaped profile.

17. The method of claim 10, wherein the second gate nitride spacers are formed by an atomic layer deposition process.

18. The method of claim 10, wherein each gate contact trench exposes a corresponding gate source/drain region in the substrate.

19. The method of claim 18 further comprising: performing a source/drain implant process to the corresponding gate source/drain region.

20. The method of claim 18, wherein each second gate nitride spacer has a uniform thickness and extends in a lengthwise direction perpendicular to the corresponding gate source/drain region.
